(19) United States
(12) Patent Application Publication
(10) Pub. No.: US 2024/0128057 A1
(43) Pub. Date: Apr. 18, 2024

(54) CONSUMABLE MEMBER, PLASMA PROCESSING APPARATUS, AND METHOD OF MANUFACTURING CONSUMABLE MEMBER

(71) Applicant: Tokyo Electron Limited, Tokyo (JP)

(72) Inventors: Kazuki MOYAMA, Miyagi (JP); Nobuyuki NAGAYAMA, Miyagi (JP); Mamoru MIURA, Miyagi (JP)

(73) Assignee: Tokyo Electron Limited, Tokyo (JP)

(21) Appl. No.: 18/398,213

(22) Filed: Dec. 28, 2023

Related U.S. Application Data
(63) Continuation of application No. PCT/JP2022/024515, filed on Jun. 20, 2022.

(30) Foreign Application Priority Data
Jun. 28, 2021 (JP) 2021-106925

(51) Int. Cl. H01J 37/32

(52) U.S. Cl. CPC H01J 37/32477; H01J 37/32715; H01J 37/32807

(57) ABSTRACT

A consumable member includes a core portion formed of the material having a first purity; and a protection portion provided at a portion worn out by plasma in the plasma processing apparatus around the core portion, and formed of the material having a second purity higher than the first purity. The material may be either quartz or ceramic.

### CROSS-REFERENCE TO RELATED APPLICATIONS

This application is a bypass continuation application of international application No. PCT/JP2022/024515 having an international filing date of Jun. 20, 2022 and designating the United States, the international application being based upon and claiming the benefit of priority from Japanese Patent Application No. 2021-106925, filed on Jun. 28, 2021, the entire contents of each are incorporated herein by reference.

### TECHNICAL FIELD

The present disclosure relates to a consumable member, a plasma processing apparatus, and a method of manufacturing the consumable member.

### BACKGROUND

In a plasma processing apparatus such as a dry etching apparatus, a consumable member to be consumed by being exposed to plasma is used. A member using quartz is used as the consumable member (for example, JP2019-220500A).

### CITATION LIST

### Patent Documents

Patent Document 1: JP2019-220500A

### SUMMARY

The present disclosure provides a technique for inexpensively manufacturing a consumable member used in a plasma processing apparatus.

A consumable member includes a core portion formed of the material having a first purity; and a protection portion provided at a portion worn out by plasma in the plasma processing apparatus around the core portion, and formed of the material having a second purity higher than the first purity. The material may be either quartz or ceramic.

According to the present disclosure, it is possible to inexpensively manufacture a consumable member used in a plasma processing apparatus.

### BRIEF DESCRIPTION OF DRAWINGS

FIG. 1 is a view illustrating an example of a plasma processing system of the embodiment.

FIG. 2 is a top view of an example of a consumable member used in a plasma processing apparatus of the present embodiment.

FIG. 3 is a cross-sectional view of the example of the consumable member used in the plasma processing apparatus of the present embodiment.

FIG. 4 is a flowchart illustrating a method of manufacturing the consumable member of a first embodiment.

FIG. 5 is a diagram illustrating the method of manufacturing the consumable member of the first embodiment.

FIG. 6 is a diagram illustrating the method of manufacturing the consumable member of the first embodiment.

FIG. 7 is a diagram illustrating the method of manufacturing the consumable member of the first embodiment.

FIG. 8 is a diagram illustrating the method of manufacturing the consumable member of the first embodiment.

FIG. 9 is a diagram illustrating the method of manufacturing the consumable member of the first embodiment.

FIG. 10 is a diagram illustrating the method of manufacturing the consumable member of the first embodiment.

FIG. 11 is a diagram illustrating the method of manufacturing the consumable member of the first embodiment.

FIG. 12 is a diagram illustrating the method of manufacturing the consumable member of the first embodiment.

FIG. 13 is a flowchart illustrating a method of manufacturing a consumable member of a second embodiment.

FIG. 14 is a diagram illustrating the method of manufacturing the consumable member of the second embodiment.

FIG. 15 is a diagram illustrating the method of manufacturing the consumable member of the second embodiment.

FIG. 16 is a diagram illustrating the method of manufacturing the consumable member of the second embodiment.

FIG. 17 is a diagram illustrating the method of manufacturing the consumable member of the second embodiment.

FIG. 18 is a diagram illustrating the method of manufacturing the consumable member of the second embodiment.

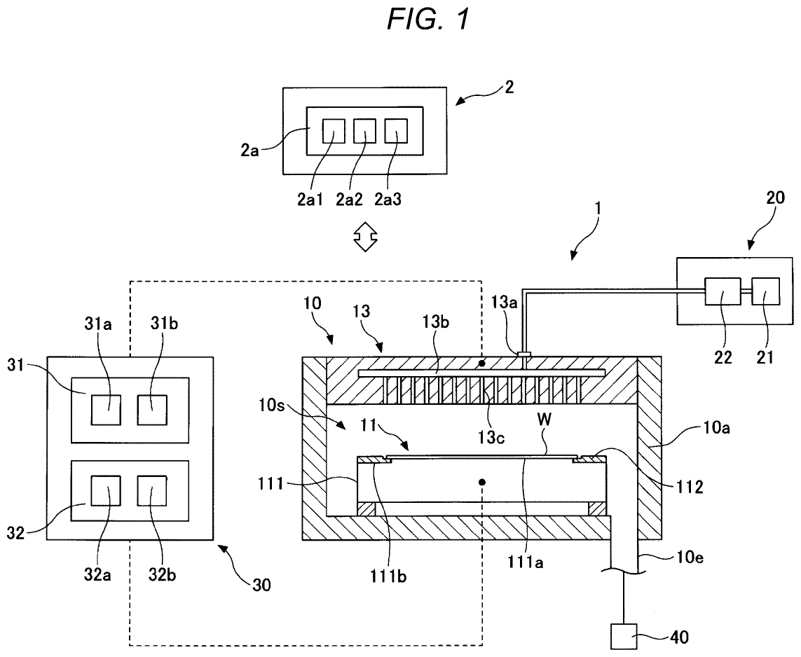

### DETAILED DESCRIPTION

Hereinafter, non-limiting exemplary embodiments of the present disclosure will be described with reference to the accompanying drawings. In the drawings, the same or corresponding members or components are denoted by the same or corresponding reference symbols, and overlapping descriptions thereof will be omitted.

### [Plasma Processing Apparatus]

Hereinafter, a configuration example of a plasma processing system will be described.

The plasma processing system includes a capacitively coupled plasma processing apparatus 1 and a controller 2. The capacitively coupled plasma processing apparatus 1 includes a plasma processing chamber 10, a gas supply 20, a power source 30, and an exhaust system 40. Further, the plasma processing apparatus 1 includes a substrate support 11 and a gas introduction unit. The gas introduction unit is configured to introduce at least one processing gas into the plasma processing chamber 10. The gas introduction unit includes a shower head 13. The substrate support 11 is disposed in the plasma processing chamber 10. The shower head 13 is disposed above the substrate support 11. In one embodiment, the shower head 13 constitutes at least a part of a ceiling of the plasma processing chamber 10. The plasma processing chamber 10 has a plasma processing space 10s defined by the shower head 13, a sidewall 10a of the plasma processing chamber 10, and the substrate support 11. The plasma processing chamber 10 has at least one gas supply port for supplying at least one processing gas into the plasma processing space 10s, and at least one gas exhaust port for exhausting the gas from the plasma processing space. The sidewall 10a is grounded. The shower head 13 and the substrate support 11 are electrically insulated from a housing of the plasma processing chamber 10.

The substrate support 11 includes a main body 111 and a ring assembly 112. The main body 111 has a central region (substrate support surface) 111a for supporting the substrate (wafer) W, and an annular region (ring support surface) 111b for supporting the ring assembly 112. The annular region 111b of the main body 111 surrounds the central region 111a of the main body 111 in a plan view. The substrate W is disposed on the central region 111a of the main body 111 and the ring assembly 112 is disposed on the annular region 111b of the main body 111 to surround the substrate W on the central region 111a of the main body 111. In one embodiment, the main body 111 includes a base and an electrostatic chuck. The base includes a conductive member. The conductive member of the base functions as a lower electrode. The electrostatic chuck is disposed on the base. The upper surface of the electrostatic chuck has a substrate support surface 111a. The ring assembly 112 includes one or more annular members. At least one of the one or more annular members is an edge ring. Although not illustrated, the substrate support 11 may include a temperature control module configured to adjust at least one of the electrostatic chuck, the ring assembly 112, and the substrate to a target temperature. The temperature control module may include a heater, a heat transfer medium, a flow path, or a combination thereof. A heat transfer fluid, such as brine or gas, flows through the flow path. Further, the substrate support 11 may include a heat transfer gas supply configured to supply a heat transfer gas between the rear surface of the substrate W and the substrate support surface 111a.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. Further, the shower head 13 includes a conductive member. The conductive member of the shower head 13 functions as an upper electrode. The gas introduction unit may include, in addition to the shower head 13, one or a plurality of side gas injectors (SGI) that are attached to one or a plurality of openings formed in the sidewall 10a.

The gas supply 20 may include at least one gas source 21 and at least one flow rate controller 22. In one embodiment, the gas supply 20 is configured to supply at least one processing gas from the respective corresponding gas sources 21 to the shower head 13 via the respective corresponding flow rate controllers 22. Each flow rate controller 22 may include, for example, a mass flow controller or a pressure-controlled flow rate controller. Further, the gas supply 20 may include one or more flow rate modulation devices that modulate or pulse flow rates of at least one processing gas.

The power source 30 includes an RF power source 31 coupled to the plasma processing chamber 10 via at least one impedance matching circuit. The RF power source 31 is configured to supply at least one RF signal (RF power), such as a source RF signal and a bias RF signal, to the conductive member of the substrate support 11 and/or the conductive member of the shower head 13. As a result, plasma is formed from at least one processing gas supplied into the plasma processing space 10s. Accordingly, the RF power source 31 may function as at least a portion of a plasma generator configured to generate plasma from one or more processing gases in the plasma processing chamber 10. Further, supplying of the bias RF signal to the conductive member of the substrate support 11 can generate a bias potential in the substrate W to draw an ion component in the formed plasma to the substrate W.

In one embodiment, the RF power source 31 includes a first RF generator 31a and a second RF generator 31b. The first RF generator 31a is coupled to the conductive member of the substrate support 11 and/or the conductive member of the shower head 13 via at least one impedance matching circuit, and configured to generate a source RF signal (source RF power) for plasma generation. In one embodiment, the source RF signal has a frequency in the range of 13 MHz to 150 MHz. In one embodiment, the first RF generator 31a may be configured to generate a plurality of source RF signals having different frequencies. The generated one or a plurality of source RF signals are supplied to the conductive member of the substrate support 11 and/or the conductive member of the shower head 13. The second RF generator 31b is coupled to the conductive member of the substrate support 11 via at least one impedance matching circuit, and configured to generate a bias RF signal (bias RF power). In one embodiment, the bias RF signal has a lower frequency than the source RF signal. In one embodiment, the bias RF signal has a frequency in the range of 400 kHz to 13.56 MHz. In one embodiment, the second RF generator 31b may be configured to generate a plurality of bias RF signals having different frequencies. The generated one or more bias RF signals are supplied to the conductive member of the substrate support 11. Further, in various embodiments, at least one of the source RF signal and the bias RF signal may be pulsed.

Further, the power source 30 may include a DC power source 32 coupled to the plasma processing chamber 10. The DC power source 32 includes a first DC generator 32a and a second DC generator 32b. In one embodiment, the first DC generator 32a is connected to the conductive member of the substrate support 11 and configured to generate a first DC signal. The generated first bias DC signal is applied to the conductive member of the substrate support 11. In one embodiment, the first DC signal may be applied to another electrode, such as an electrode in an electrostatic chuck. In one embodiment, the second DC generator 32b is configured to be connected to the conductive member of the shower head 13 and to generate a second DC signal. The generated second DC signal is applied to the conductive member of the shower head 13. In various embodiments, at least one of the first and second DC signals may be pulsed. The first and second DC generators 32a and 32b may be provided in addition to the RF power source 31, and the first DC generator 32a may be provided instead of the second RF generator 31b.

The exhaust system 40 may be connected to, for example, a gas exhaust port 10e disposed at a bottom portion of the plasma processing chamber 10. The exhaust system 40 may include a pressure adjusting valve and a vacuum pump. The pressure in the plasma processing space 10s is adjusted by the pressure adjusting valve. The vacuum pump may include a turbo molecular pump, a dry pump, or a combination thereof.

The controller 2 processes computer-executable instructions for instructing the plasma processing apparatus 1 to execute various steps described herein below. The controller 2 may be configured to control the respective components of the plasma processing apparatus 1 to execute the various steps described herein below. In an embodiment, part or all of the controller 2 may be included in the plasma processing apparatus 1. The controller 2 may include, for example, a computer 2a. For example, the computer 2a may include a processor (central processing unit (CPU)) 2a1, a storage unit 2a2, and a communication interface 2a3. The processor 2a1 may be configured to perform various control operations based on a program stored in the storage unit 2a2. The storage unit 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

### <Consumable Member Used in Plasma Processing Apparatus>

A member used in the plasma processing chamber 10 of the plasma processing apparatus 1 such as a dry etching apparatus is exposed to the plasma. The member exposed to the plasma and worn out, which is used in the plasma processing chamber 10 of the plasma processing apparatus 1 such as the dry etching apparatus, is periodically replaced as the consumable member.

Examples of the consumable member include the annular member (the edge ring or a cover ring) of the ring assembly 112, an insulation ring provided on a side surface of the electrostatic chuck, an upper electrode cover provided on a ceiling surface of the shower head 13, a shield ring that presses the upper electrode cover, or a support member that supports the shower head 13.

The consumable member is formed of, for example, quartz or ceramics. A wear location of the consumable member and a wear depth at each wear location can be predicted according to using conditions or the like. It is desirable that the wear location is formed using a high-purity material for the purpose of preventing contamination of the processing substrate. On the other hand, in the consumable member, a portion not consumed occupies a large portion of a volume of the member. Since there is no influence on the processing substrate, a low-purity material can be used as the portion not consumed.

Therefore, in the consumable member used in the plasma processing apparatus according to the present embodiment, the portion not worn out is made of the inexpensive low-purity material, and the worn-out portion is molded with a high-purity slurry material.

### <Edge Ring 115>

As an example of the consumable member, an edge ring 115 that is the annular member of the ring assembly 112 will be described by way of example. Here, the edge ring 115 is described as the consumable member, but the consumable member is not limited to the edge ring. The consumable member may be, for example, the cover ring, the insulation ring provided on the side surface of the electrostatic chuck, the upper electrode cover provided on the ceiling surface of the shower head 13, the shield ring that presses the upper electrode cover, or the support member that supports the shower head 13.

Here, quartz is described as the material of the edge ring 115, but ceramics may be used as the material of the consumable member.

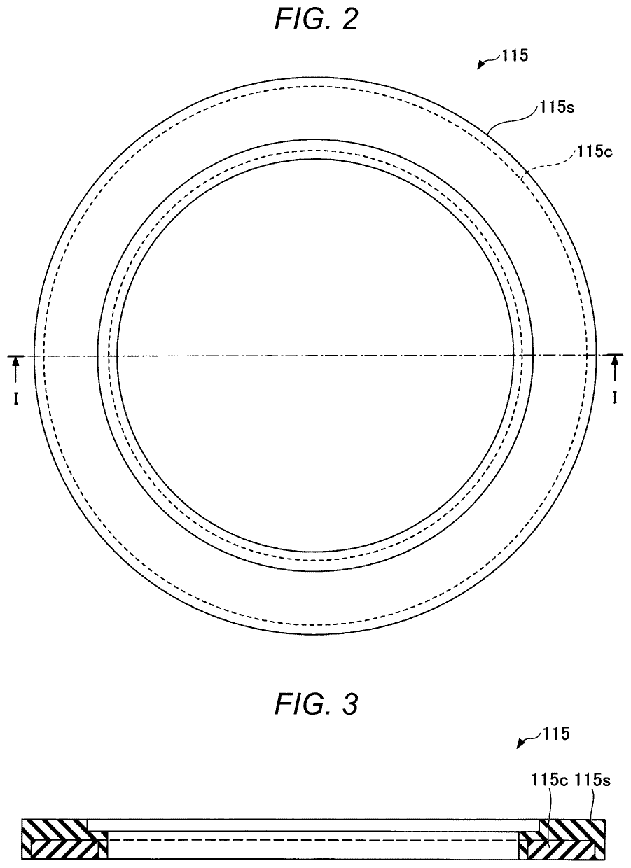

FIG. 2 is a top view of the edge ring 115 that is an example of the consumable member according to the present embodiment. FIG. 3 is a cross-sectional view of the edge ring 115 that is the example of the consumable member according to the present embodiment. Specifically, FIG. 3 is a cross-sectional view taken along a line I-I in FIG. 2. In the cross-sectional view illustrated below, a cross-sectional view of a cross section corresponding to a cross section in FIG. 3 is illustrated.

The edge ring 115 is one of the annular members of the ring assembly 112. The edge ring 115 is disposed around the substrate W. The edge ring 115 is formed of quartz. The edge ring 115 has a core portion 115c and a protection portion 115s.

The core portion 115c is provided at a portion not worn out by the plasma and not exposed to the plasma during use in the plasma processing apparatus 1. The core portion 115c is made of quartz having a purity lower than that of the quartz that constitutes the protection portion 115s. The core portion 115c may be formed by a slurry casting method as described later, or may be formed by solidifying molten quartz.

The protection portion 115s is provided at a portion worn out by the plasma during use in the plasma processing apparatus 1. Further, the protection portion 115s is provided at a portion of the core portion 115c that may be worn out by the plasma with at least a constant thickness such that the core portion 115c is not worn out by the plasma during use in the plasma processing apparatus 1. The protection portion 115s is made of high-purity quartz. Since the protection portion 115s may be worn out by the plasma during use in the plasma processing apparatus 1, the protection portion 115s is made of the high-purity quartz so as not to contaminate the processing substrate.

It is desirable that the core portion 115c and the protection portion 115s are formed of the same materials having different purities. The edge ring 115 is exposed to the plasma and raised to a high temperature. In a case where the core portion 115c and the protection portion 115s are formed of different materials, the materials may crack or peel off due to a difference in thermal expansion coefficients when the edge ring 115 is at a high temperature. Since the core portion 115c and the protection portion 115s are formed of the same materials, the edge ring 115 can prevent the cracking and the peeling off when a temperature becomes high.

For example, in the plasma processing apparatus 1, when the plasma is generated for about time t1, the edge ring 115 is assumed to be worn out by about ΔT millimeter depending on a location. When expected usage time is time t2, a thickness of a worn-out portion of the protection portion 115s is at least ΔT×t2/t1 millimeters. The thickness of the worn-out portion of the protection portion 115s is, for example, 0.2 to 2 millimeters.

### First Embodiment

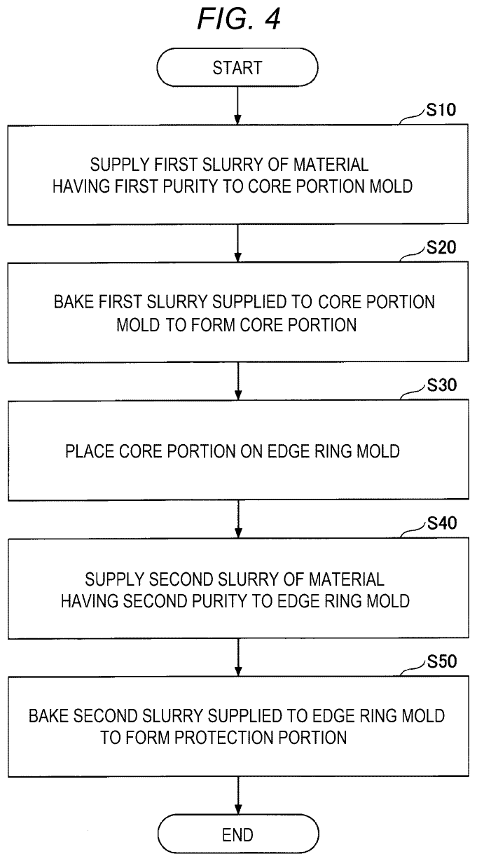

Next, a manufacturing method will be described using the edge ring 115 as an example of the consumable member. FIG. 4 is a flowchart illustrating the method of manufacturing the consumable member according to the first embodiment.

First, a step of forming the core portion 115c will be described. The core portion 115c is formed by the slurry casting method. A first slurry 120 is prepared to form the core portion 115c by the slurry casting method. The first slurry 120 is created by mixing raw material powder of the quartz that constitutes the core portion 115c and a liquid such as water or alcohol. A purity of the raw material powder of the first slurry 120 is a standard purity.

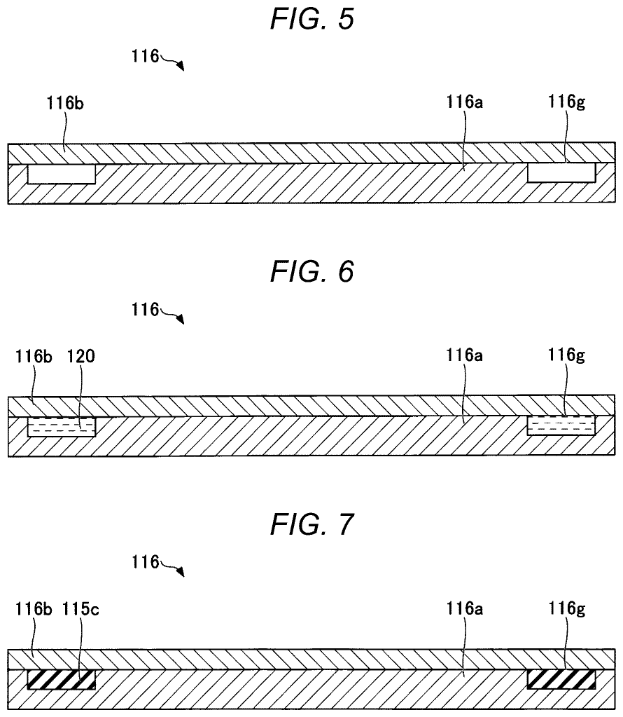

The first slurry 120 having the first purity is supplied to a core portion mold 116 (step S10, a step of supplying the first slurry of the material having the first purity to the core portion mold). FIG. 5 is a cross-sectional view of the core portion mold 116. The core portion mold 116 includes a base 116a and a lid 116b. The base 116a has a groove 116g. The lid 116b is placed on the base 116a, and the first slurry 120 is supplied from an introduction port (not illustrated) to the groove 116g.

A dimension of the groove 116g is formed to be slightly larger than a dimension of the core portion 115c in consideration of the dimension being finally contracted by baking the first slurry 120. FIG. 6 is a cross-sectional view illustrating a state where the first slurry 120 is supplied to the groove 116g of the core portion mold 116.

The first slurry 120 is a slurry for forming quartz having a standard purity. When compared with a second slurry 125 to be described later, the purity of the quartz of the raw material powder is low. Since the core portion 115c is a portion not worn out by the plasma, the core portion 115c is formed using the first slurry 120 having the standard purity.

Next, the first slurry 120 supplied to the core portion mold 116 is baked to form the core portion 115c (step S20, a step of baking the first slurry supplied to the core portion mold to form the core portion). FIG. 7 is a cross-sectional view illustrating a state where the first slurry 120 supplied to the core portion mold 116 is baked to form the core portion 115c.

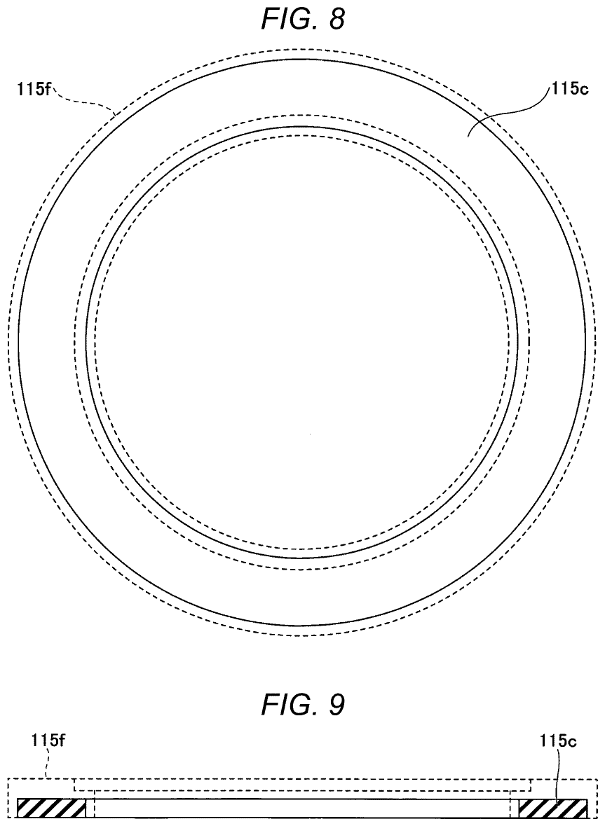

Next, the formed core portion 115c is removed from the core portion mold 116. FIG. 8 is a top view illustrating the core portion 115c removed from the core portion mold 116. FIG. 9 is a cross-sectional view illustrating the core portion 115c removed from the core portion mold 116. In FIGS. 8 and 9, the finally formed edge ring 115 is indicated by a dotted line as a virtual edge ring 115f.

Next, a step of forming the protection portion 115s will be described. The protection portion 115s is formed by the slurry casting method. The second slurry 125 is prepared to form the protection portion 115s by the slurry casting method. The second slurry 125 is created by mixing the raw material powder of the quartz that constitutes the protection portion 115s and a liquid such as water or alcohol. A purity of the raw material powder of the second slurry 125 is a purity higher than the purity of the raw material powder of the first slurry 120.

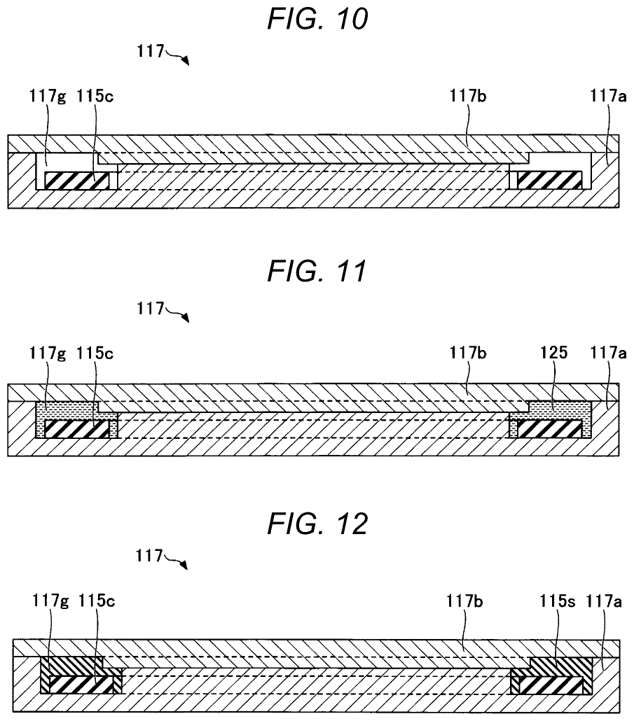

The core portion 115c is placed on an edge ring mold 117 (step S30, a step of placing the core portion on the edge ring mold). FIG. 10 is a cross-sectional view illustrating a state where the core portion 115c is placed on the edge ring mold 117.

The edge ring mold 117 includes a base 117a and a lid 117b. When the lid 117b is placed on the base 117a, a groove 117g is formed. A dimension of the groove 117g is slightly larger than the dimension of the protection portion 115s in consideration of the dimension being finally contracted by baking the second slurry 125.

Before the lid 117b is placed on the base 117a, the core portion 115c is placed on the base 117a. Then, the lid 117b is placed on the base 117a. When the lid 117b is placed on the base 117a, the core portion 115c is located inside the groove 117g.

Next, the second slurry 125 having a second purity higher than the first purity is supplied to the edge ring mold 117 where the core portion 115c is placed (step S40, a step of supplying the second slurry of the material having the second purity higher than the first purity to the edge ring mold).

The second slurry 125 is supplied from an introduction port (not illustrated) to the groove 117g. FIG. 11 is a cross-sectional view illustrating a state where the second slurry 125 is supplied to the groove 117g of the edge ring mold 117.

The protection portion 115s of the edge ring 115 is provided at a portion that can be worn out by the plasma. Therefore, the protection portion 115s is formed of high-purity quartz. In order to form the protection portion 115s by using the high-purity quartz, the second slurry 125 having the second purity higher than the first purity is used to form the protection portion 115s.

Next, the second slurry 125 supplied to the edge ring mold 117 is baked to form the protection portion 115s (step S50, a step of baking the second slurry supplied to the edge ring mold to form the protection portion). FIG. 12 is a cross-sectional view illustrating a state where the second slurry 125 supplied to the edge ring mold 117 is baked to form the protection portion 115s.

Finally, the edge ring 115 is removed from the edge ring mold 117. The edge ring 115 illustrated in FIGS. 2 and 3 is manufactured by the steps described above.

### Operations and Effects

According to the method of manufacturing the consumable member of the first embodiment, the portion worn out by the plasma can be formed of the high-purity quartz, and the portion not worn out by the plasma can be formed of the quartz having the purity lower than that of the high-purity quartz.

The portion not exposed to the plasma is formed of the quartz having the purity lower than that of the high-purity quartz, whereby a cost of the consumable member can be reduced. Further, the high-purity quartz material has a problem in availability. However, an amount of the high-purity quartz material used can be reduced by reducing the portion of the high-purity quartz material.

The high-purity raw material powder of the slurry can be obtained by highly purifying the low-purity raw material powder of the slurry. Therefore, the availability of the raw material powder of the slurry can be improved by manufacturing the consumable member by the slurry casting method.

In the method of manufacturing the consumable member according to the present embodiment, the core portion 115c is formed by the slurry casting method, but the core portion 115c may be formed using a method other than the slurry casting method.

### Second Embodiment

Next, a method of manufacturing the consumable member according to a second embodiment will be described. The method of manufacturing a quartz material according to the second embodiment is different from the method of manufacturing the consumable member according to the first embodiment in that cutting is performed and a shape of a final product is created in a final step.

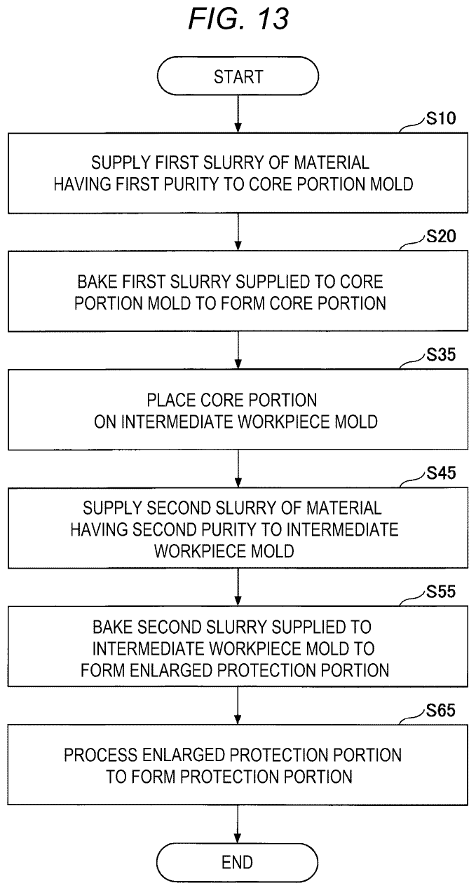

FIG. 13 is a flowchart illustrating the method of manufacturing the consumable member according to the second embodiment. Since steps S10 and S20 are the same as those in the method of manufacturing the consumable member according to the first embodiment, description thereof will be omitted.

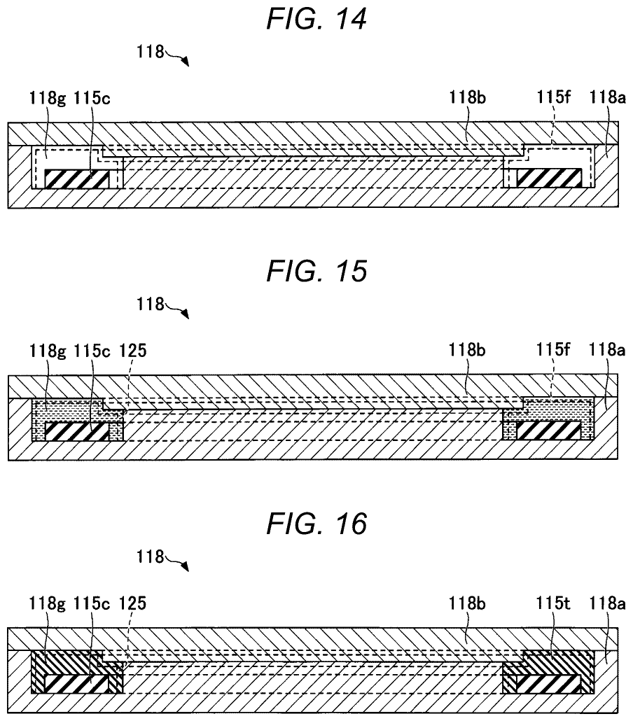

After step S20, the core portion 115c is placed on an intermediate workpiece mold 118 (step S35, a step of placing the core portion on the intermediate workpiece mold). FIG. 14 is a cross-sectional view illustrating a state where the core portion 115c is placed on the intermediate workpiece mold 118.

The intermediate workpiece mold 118 includes a base 118a and a lid 118b. When the lid 118b is placed on the base 118a, a groove 118g is formed. A dimension of the groove 118g is larger than that of the edge ring 115 including a cutting allowance. In FIG. 14, the finally formed edge ring 115 is indicated by a dotted line as the virtual edge ring 115f.

The core portion 115c is placed on the base 118a before the lid 118b is placed on the base 118a. Then, the lid 118b is placed on the base 118a. When the lid 118b is placed on the base 118a, the core portion 115c is located inside the groove 118g.

Next, the second slurry 125 having the second purity higher than the first purity is supplied to the intermediate workpiece mold 118 where the core portion 115c is placed (step S45, a step of supplying the second slurry having the second purity higher than the first purity to the intermediate workpiece mold).

The second slurry 125 is supplied from an introduction port (not illustrated) to the groove 118g. FIG. 15 is a cross-sectional view illustrating a state where the second slurry 125 is supplied to the groove 118g of the intermediate workpiece mold 118.

The protection portion 115s of the edge ring 115 is provided at a portion exposed to the plasma. Therefore, the protection portion 115s is formed of high-purity quartz. In order to form the protection portion 115s by using high-purity quartz, the second slurry 125 of the material having the second purity higher than the first purity is used to form the protection portion 115s.

Next, the second slurry 125 supplied to the intermediate workpiece mold 118 is baked to form an enlarged protection portion 115t (step S55, a step of baking the second slurry supplied to the intermediate workpiece mold to form the enlarged protection portion). FIG. 16 is a cross-sectional view illustrating a state where the second slurry 125 supplied to the intermediate workpiece mold 118 is baked to form the enlarged protection portion 115t.

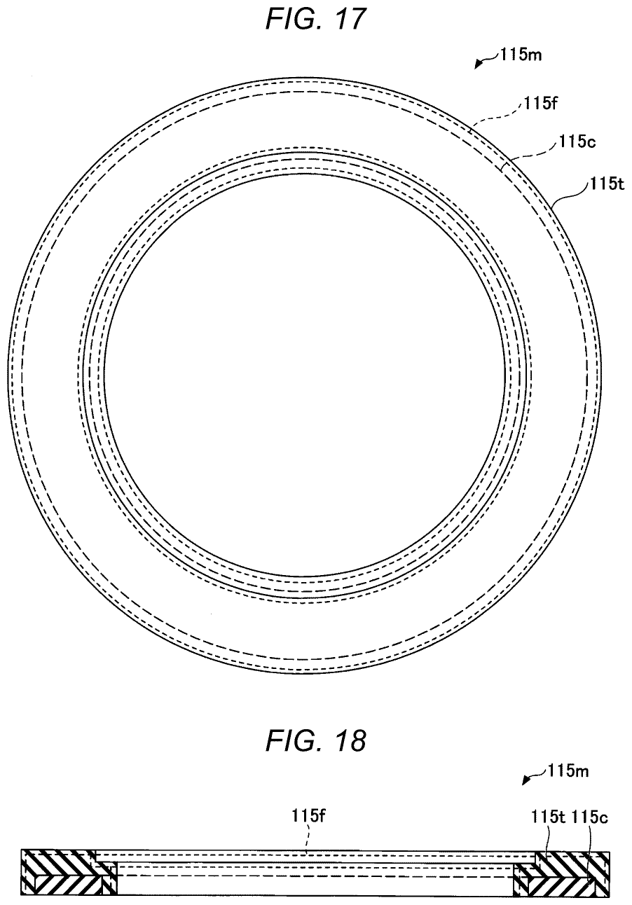

Next, the enlarged protection portion 115t is cut to form the protection portion 115s (step S65, a step of processing the enlarged protection portion to form the protection portion). FIG. 17 is a top view of an intermediate workpiece 115m obtained by forming the enlarged protection portion 115t in step S55 and removing the enlarged protection portion 115t from the intermediate workpiece mold 118. FIG. 18 is a cross-sectional view of the intermediate workpiece 115m obtained by forming the enlarged protection portion 115t in step S55 and removing the enlarged protection portion 115t from the intermediate workpiece mold 118. In FIGS. 17 and 18, the finally formed edge ring 115 is indicated by a dotted line as the virtual edge ring 115f.

In the intermediate workpiece 115m, the portion of the enlarged protection portion 115t is larger than the final edge ring 115. In step S65, the intermediate workpiece 115m is cut to create the edge ring 115.

### Operations and Effects

According to the method of manufacturing the consumable member of the second embodiment, the final consumable member can be formed with high dimensional accuracy in addition to the effects of the method of manufacturing the consumable member according to the first embodiment.

### Modification Examples

The core portion 115c placed on the edge ring mold 117 or the intermediate workpiece mold 118 is not limited to the core portion 115c. For example, in order to reproduce the edge ring 115 that has been used once, a part of the protection portion 115s may remain at the core portion 115c.

The embodiments disclosed this time should be considered to be illustrative in all respects and not restrictive. The embodiment described above may be omitted, replaced, or modified in various forms without departing from the scope and spirit of the appended claims.

1. A consumable member, comprising:
a core portion formed of a material having a first purity; and
a protection portion provided at a portion worn out by plasma in a plasma processing apparatus around the core portion, and formed of the material having a second purity higher than the first purity.

2. The consumable member according to claim 1, wherein
the consumable member is at least any one of an edge ring, a cover ring, an insulation ring provided on a side surface of an electrostatic chuck, an upper electrode cover provided on a ceiling surface of a shower head, a shield ring that presses the upper electrode cover, and a support member that supports the shower head.

3. The consumable member according to claim 1, wherein
the protection portion is formed around the core portion by a slurry casting method.

4. The consumable member according to claim 2, wherein
the protection portion is formed around the core portion by a slurry casting method.

5. A plasma processing apparatus comprising:
a chamber; and
the consumable member according to claim 1.

6. The consumable member according to claim 1, wherein the material is either quartz or ceramic.

7. A method of manufacturing a consumable member used in a plasma processing apparatus, the method comprising:
(a) placing a core portion formed of a material having a first purity on a mold;
(b) supplying a slurry of the material having a second purity higher than the first purity to the mold; and
(c) baking the slurry supplied to the mold to form a protection portion.

8. The method according to claim 7, wherein the material is either quartz or ceramic.

9. The method according to claim 7, further comprising:
before the (a), supplying a second slurry of the material having the first purity to a core portion mold, and baking the second slurry supplied to the core portion mold to form the core portion.

10. A method of manufacturing a consumable member used in a plasma processing apparatus, the method comprising:
(a) placing a core portion formed of a material having a first purity on a mold;
(b) supplying a slurry of the material having a second purity higher than the first purity to the mold;
(c) baking the slurry supplied to the mold to form an enlarged protection portion; and
(d) processing the enlarged protection portion to form a protection portion.

11. The method according to claim 10, wherein the material is either quartz or ceramic.

12. The method according to claim 10, further comprising:
before the (a), supplying a second slurry of the material having the first purity to a core portion mold, and baking the second slurry supplied to the core portion mold to form the core portion.
